(19) United States
(12) Patent Application Publication
(10) Pub. No.: US 2019/0180946 A1
(43) Pub. Date: Jun. 13, 2019

(54) ORGANIC-INORGANIC HYBRID SOLAR CELL AND METHOD FOR MANUFACTURING ORGANIC-INORGANIC HYBRID SOLAR CELL

(71) Applicant: LG CHEM, LTD., Seoul (KR)

(72) Inventors: Yongnam KIM, Daejeon (KR); Sang Jun PARK, Daejeon (KR); Seiyong KIM, Daejeon (KR); Deok Hwan KIM, Daejeon (KR)

(21) Appl. No.: 16/320,994

(22) PCT Filed: Sep. 19, 2017
(86) PCT No.: PCT/KR2017/010240

§ 371 Date: Jan. 25, 2019

(30) Foreign Application Priority Data
Sep. 23, 2016 (KR) 10-2016-0122344
Sep. 15, 2017 (KR) 10-2017-0118790

(51) Int. Cl. H01G 9/20; H01G 9/00; H01L 51/42; H01L 51/00

(52) U.S. Cl. CPC H01G 9/2009; H01G 9/0036; H01L 51/0077; H01L 51/0007; H01L 51/426

(57) ABSTRACT

An organic-inorganic complex solar cell including a first electrode, a first common layer provided on the first electrode, a light absorbing layer provided on the first common layer and including a compound having a perovskite structure, a second common layer provided on the light absorbing layer, a third common layer provided on the second common layer, and a second electrode provided on the third common layer, in which the first common layer includes a first metal oxide nanoparticle, the second common layer includes a second metal oxide nanoparticle, and the third common layer includes a fullerene derivative.

### TECHNICAL FIELD

This application claims priority to and the benefit of Korean Patent Application Nos. 10-2016-0122344 and 10-2017-0118790 filed in the Korean Intellectual Property Office on Sep. 23, 2016 and Sep. 15, 2017, respectively, the entire contents of which are incorporated herein by reference.

The present specification relates to an organic-inorganic complex solar cell and a method for manufacturing the same.

### BACKGROUND ART

In order to solve the global environmental problems caused by the depletion of fossil fuels and the use thereof, studies have been actively conducted on alternative energy sources, which may be regenerated and are clean, such as solar energy, wind power, and water power. Among them, interests in solar cells which change electric energy directly from the sunlight have been greatly increased. Here, the solar cell means a cell which produces current-voltage by using a photovoltaic effect of absorbing photoenergy from the sunlight to generate electrons and holes.

Organic-inorganic complex perovskite materials have recently drawn attention as a light absorbing material for organic-inorganic complex solar cells due to the characteristics in which the absorption coefficient is high and the material can be easily synthesized through a solution process.

However, an organic-inorganic complex solar cell to which an existing perovskite material is applied has a problem in that it is difficult to secure reliability such as heat resistance and light resistance characteristics. In order to overcome the problem, studies have been conducted on the application of a metal oxide-based common layer instead of an organic material-based common layer.

### DETAILED DESCRIPTION OF THE INVENTION

### Technical Problem

The present specification provides an organic-inorganic complex solar cell having excellent stability and energy conversion efficiency and a method for manufacturing an organic-inorganic complex solar cell.

### Technical Solution

An exemplary embodiment of the present specification provides an organic-inorganic complex solar cell including:

a first electrode;

a first common layer provided on the first electrode;

a light absorbing layer provided on the first common layer and including a compound having a perovskite structure on the first common layer;

a second common layer provided on the light absorbing layer;

a third common layer provided on the second common layer; and

a second electrode provided on the third common layer,

in which the first common layer includes a first metal oxide nanoparticle,

the second common layer includes a second metal oxide nanoparticle, and

the third common layer includes a fullerene derivative.

Another exemplary embodiment of the present specification provides a method for manufacturing an organic-inorganic complex solar cell, the method including:

forming a first electrode;

forming a first common layer on the first electrode;

forming a light absorbing layer including a compound having a perovskite structure on the first common layer;

forming a second common layer on the light absorbing layer;

forming a third common layer on the second common layer; and

forming a second electrode on the third common layer,

in which the first common layer includes a first metal oxide nanoparticle,

the second common layer includes a second metal oxide nanoparticle, and

the third common layer includes a fullerene derivative.

### Advantageous Effects

An organic-inorganic complex solar cell according to an exemplary embodiment of the present specification has an effect of improving light resistance.

Further, the organic-inorganic complex solar cell according to an exemplary embodiment of the present specification has an effect in that two common layers are stacked on a light absorbing layer without any damage to the light absorbing layer.

In addition, the organic-inorganic complex solar cell according to an exemplary embodiment of the present specification can absorb a broad light spectrum and thus has an effect in that the light energy loss is reduced, and the energy conversion efficiency is increased.

### BRIEF DESCRIPTION OF DRAWINGS

FIG. 1 exemplifies a structure of an organic-inorganic complex solar cell according to an exemplary embodiment of the present specification.

FIG. 2 illustrates a scanning electron microscope (SEM) image of a cross-section of an organic-inorganic complex solar cell manufactured in an Example of the present specification.

FIG. 3(A) illustrates a value of change in short-circuit current (Jsc) according to the time in each of organic-inorganic complex solar cells manufactured in the Example and Comparative Example 2 of the present specification.

FIG. 3(B) illustrates a value of change in open-circuit voltage (V_{oc}) according to the time in each of the organic-inorganic complex solar cells manufactured in the Example and Comparative Example 2 of the present specification.

FIG. 3(C) illustrates a value of change in efficiency (PCE) according to the time in each of the organic-inorganic complex solar cells manufactured in the Example and Comparative Example 2 of the present specification.

FIG. 3(D) illustrates a value of change in fill factor (FF) according to the time in each of the organic-inorganic complex solar cells manufactured in the Example and Comparative Example 2 of the present specification.

### EXPLANATION OF REFERENCE NUMERALS AND SYMBOLS

101: Substrate
102: First electrode
103: First common layer
104: Light absorbing layer
105: Second common layer
106: Third common layer
107: Second electrode

### BEST MODE

Hereinafter, the present specification will be described in detail.

When one part “includes” one constituent element in the present specification, unless otherwise specifically described, this does not mean that another constituent element is excluded, but means that another constituent element may be further included.

When one member is disposed “on” another member in the present specification, this includes not only a case where the one member is brought into contact with another member, but also a case where still another member is present between the two members.

An organic-inorganic complex solar cell according to the present specification includes:

a first electrode;

a first common layer provided on the first electrode;

a light absorbing layer provided on the first common layer and including a compound having a perovskite structure;

a second common layer provided on the light absorbing layer;

a third common layer provided on the second common layer; and

a second electrode provided on the third common layer,

in which the first common layer includes a first metal oxide nanoparticle,

the second common layer includes a second metal oxide nanoparticle, and

the third common layer includes a fullerene derivative.

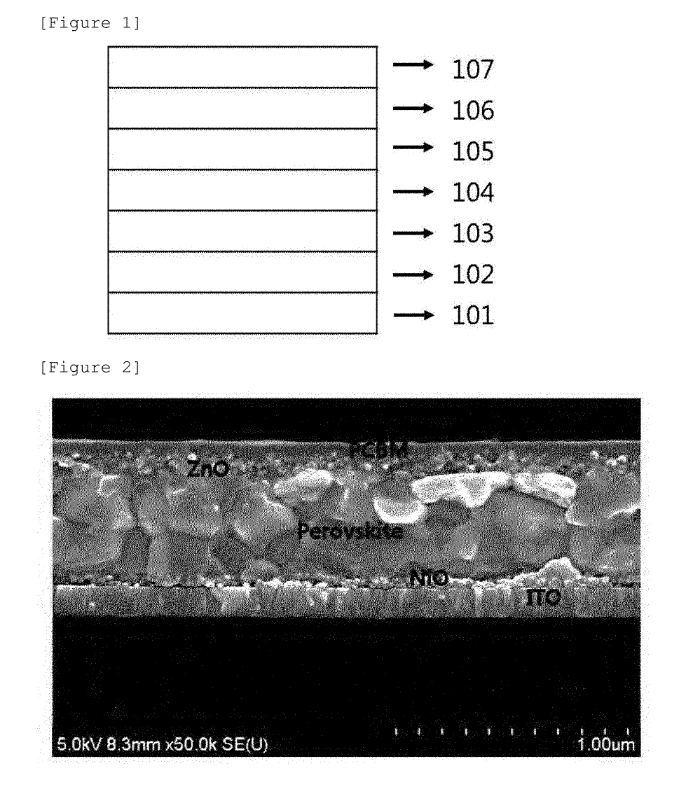

FIG. 1 exemplifies a structure of an organic-inorganic complex solar cell according to an exemplary embodiment of the present specification. Specifically, FIG. 1 exemplifies a structure of an organic-inorganic complex solar cell in which a first electrode 102 is provided on a substrate 101, a first common layer 103 is provided on the first electrode 102, a light absorbing layer 104 is provided on the first common layer 103, a second common layer 105 is provided on the light absorbing layer 104, a third common layer 106 is provided on the second common layer 105, and a second electrode 107 is provided on the third common layer 106. The organic-inorganic complex solar cell according to the present specification is not limited to the stacking structure in FIG. 1, and may further include an additional member.

In an exemplary embodiment of the present specification, the light absorbing layer includes a compound having a perovskite structure represented by the following Chemical Formula 1 or 2.

AMX₃ [Chemical Formula 1]

A′_{y}A″_{(1-y)}M′X′_{Z}X″_{(3-z)} [Chemical Formula 2]

In Chemical Formula 1 or 2,

A′ and A″ are different from each other, and A, A′, and A″ are each a monovalent cation selected from CₙH₂ₙ₊₁NH₃⁺, NH₄⁺, HC(NH₂)₂⁺, Cs⁺, NF₄⁺, NCl₄⁺, PF₄⁺, PCl₄⁺, CH₃PH₃⁺, CH₃AsH₃⁺, CH₃SbH₃⁺, PH₄⁺, AsH₄⁺, and SbH₄⁺,

M and M′ are each a divalent metal ion selected from Cu²⁺, Ni²⁺, Co²⁺, Fe²⁺, Mn²⁺, Cr²⁺, Pd²⁺, Cd²⁺, Ge²⁺, Sn²⁺, Bi²⁺, Pb²⁺, and Yb²⁺,

X, X′, and X″ are each a halogen ion,

n is an integer from 1 to 9,

0<y<1, and

0<z<3.

In an exemplary embodiment of the present specification, the compound having the perovskite structure in the light absorbing layer may include a single cation. In the present specification, the single cation means that one kind of monovalent cation is used. That is, in Chemical Formula 1, only one kind of monovalent cation is selected as A. For example, in Chemical Formula 1, A may be CₙH₂ₙ₊₁NH₃⁺, and n may be an integer from 1 to 9.

In an exemplary embodiment of the present specification, the compound having the perovskite structure in the light absorbing layer may include a complex cation.

In the present specification, the complex cation means that two or more kinds of monovalent cations are used. That is, in Chemical Formula 2, different monovalent cations are selected as each of A′ and A″. For example, in Chemical Formula 2, A′ may be CₙH₂ₙ₊₁NH₃⁺, A″ may be HC(NH₂)₂⁺, and n may be an integer from 1 to 9.

In an exemplary embodiment of the present specification, M and M′ may be Pb²⁺.

In an exemplary embodiment of the present specification, the first common layer includes a first metal oxide nanoparticle, and the second common layer includes a second metal oxide nanoparticle.

In an exemplary embodiment of the present specification, the first metal oxide nanoparticle and the second metal oxide nanoparticle each include at least one of Ni oxide, Cu oxide, Zn oxide, Ti oxide, and Sn oxide, and the first metal oxide nanoparticle and the second metal oxide nanoparticle are different from each other.

Specifically, the first metal oxide nanoparticle may include at least one of Ni oxide and Cu oxide, and the second metal oxide nanoparticle may include at least one of Zn oxide, Ti oxide, and Sn oxide.

In an exemplary embodiment of the present specification, the first common layer, the second common layer, and the third common layer each mean an electron transporting layer or a hole transporting layer.

In an exemplary embodiment of the present specification, the first common layer may be a hole transporting layer, the second common layer may be a first electron transporting layer, and the third common layer may be a second electron transporting layer.

In an exemplary embodiment of the present specification, the first common layer may be an electron transporting layer, the second common layer may be a first hole transporting layer, and the third common layer may be a second hole transporting layer.

In an exemplary embodiment of the present specification, the third common layer may include a fullerene derivative. In this case, the third common layer is an electron transporting layer.

In an exemplary embodiment of the present specification, the first common layer may have a thickness of 3 nm to 150 nm. In the present specification, the thickness of the first common layer means a width between the surface of which the first common layer is brought into contact with the first electrode and the surface of which the first common layer is brought into contact with the light absorbing layer.

In an exemplary embodiment of the present specification, the second common layer may have a thickness of 3 nm to 150 nm. In the present specification, the thickness of the second common layer means a width between the surface of which the second common layer is brought into contact with the light absorbing layer and the surface of which the second common layer is brought into contact with the third common layer.

In an exemplary embodiment of the present specification, the third common layer may have a thickness of 3 nm to 150 nm. In the present specification, the thickness of the third common layer means a width between the surface of which the third common layer is brought into contact with the second common layer and the surface of which the third common layer is brought into contact with the second electrode.

In an exemplary embodiment of the present specification, the light absorbing layer has a thickness of 100 nm to 1,000 nm.

Another exemplary embodiment of the present specification provides a method for manufacturing an organic-inorganic complex solar cell, the method including:

forming a first electrode;

forming a first common layer on the first electrode;

forming a light absorbing layer including a compound having a perovskite structure on the first common layer;

forming a second common layer on the light absorbing layer;

forming a third common layer on the second common layer; and

forming a second electrode on the third common layer,

in which the first common layer includes a first metal oxide nanoparticle,

the second common layer includes a second metal oxide nanoparticle, and

the third common layer includes a fullerene derivative.

In an exemplary embodiment of the present specification, the forming of the first common layer includes coating a first solution including a first metal oxide nanoparticle and a first dispersant onto the first electrode.

In an exemplary embodiment of the present specification, the forming of the second common layer includes coating a second solution including a second metal oxide nanoparticle and a second dispersant onto the light absorbing layer.

In an exemplary embodiment of the present specification, the first solution and the second solution each include a non-polar solvent. Specifically, examples of each of the first solution and the second solution include chlorobenzene, dichlorobenzene, xylene, benzene, hexane, diethyl ether, toluene, and the like, but are not limited thereto.

In general, the metal oxide nanoparticle is dispersed in a polar solvent such as a water-based solvent and an alcoholic solvent, and since a compound having a perovskite structure, which is applied to a light absorbing layer of an organic-inorganic complex solar cell, is vulnerable to a polar solvent, it is difficult to apply a metal oxide nanoparticle to a light absorbing layer.

In an exemplary embodiment of the present specification, there is an advantage in that a dispersant is included, and thus a non-polar solvent including a metal oxide nanoparticle can be applied to an upper portion of a light absorbing layer including a compound having a perovskite structure.

In an exemplary embodiment of the present specification, a dispersant may mean at least one of a first dispersant and a second dispersant.

In an exemplary embodiment of the present specification, a metal oxide nanoparticle may mean at least one of a first metal oxide nanoparticle and a second metal oxide nanoparticle.

In an exemplary embodiment of the present specification, the dispersant may be 4-vinylpridine, a-methylstyrene, butyl acrylate, polyethylene glycol, a mixture thereof, or a polymer thereof.

In an exemplary embodiment of the present specification, the first solution includes the first dispersant in an amount of more than 0 wt and 10 wt % or less based on the metal nanoparticles. When the dispersant satisfies the range, there is an effect in that it is possible to obtain high photoelectric conversion efficiency because an increase in electrical resistance in a device is reduced.

In an exemplary embodiment of the present specification, the second solution includes the second dispersant in an amount of more than 0 wt and 10 wt % or less based on the metal nanoparticle. When the dispersant satisfies the range, there is an effect in that it is possible to obtain high photoelectric conversion efficiency because an increase in electrical resistance in a device is reduced.

In an exemplary embodiment of the present specification, the light absorbing layer may be formed by a method such as spin coating, slit coating, dip coating, inkjet printing, gravure printing, spray coating, doctor blade, bar coating, brush painting, or thermal deposition.

In the present specification, a fullerene derivative means a compound including fullerene, in which a part of fullerene atoms is substituted with another atom or an atom group. Examples of the fullerene derivative include [6,6]-phenyl-C₆₁-butyric acid methyl ester (PCBM), indene-C₆₀ bisadduct (ICBA), indene-C₆₀ monoadduct (ICMA), and the like, but are not limited thereto.

In an exemplary embodiment of the present specification, the forming of the third common layer includes coating a third solution including a fullerene derivative onto the second common layer.

In an exemplary embodiment of the present specification, the fullerene derivative in the third solution may be included in an amount of 0.1 wt % to 5 wt %.

In an exemplary embodiment of the present specification, the third solution may be chlorobenzene, but is not limited thereto.

In an exemplary embodiment of the present specification, for the coating of the first solution, the second solution, and the third solution any method can be used as long as the method is a method used in the art. For example, the method may be spin coating, dip coating, or spray coating, but is not limited thereto.

In an exemplary embodiment of the present specification, the organic-inorganic complex solar cell may further include a substrate. Specifically, the substrate may be provided at a lower portion of the first electrode.

In an exemplary embodiment of the present specification, as the substrate, it is possible to use a substrate having excellent transparency, surface smoothness, handling easiness, and waterproofing property. Specifically, a glass substrate, a thin film glass substrate, or a plastic substrate may be used. The plastic substrate may include a film such as polyethylene terephthalate (PET), polyethylene naphthalate (PEN), polyether ether ketone, and polyimide in the form of a single layer or a multi-layer. However, the substrate is not limited thereto, and a substrate typically used for an organic-inorganic complex solar cell may be used.

In an exemplary embodiment of the present specification, the first electrode may be an anode, and the second electrode may be a cathode. Further, the first electrode may be a cathode, and the second electrode may be an anode.

In an exemplary embodiment of the present specification, the first electrode may be a transparent electrode, and the organic-inorganic complex solar cell may absorb light by way of the first electrode.

When the first electrode is a transparent electrode, the first electrode may be a conductive oxide such as indium-tin oxide (ITO), indium-zinc oxide (IZO), or fluorine-doped tin oxide (FTO). Furthermore, the first electrode may be a semi-transparent electrode. When the first electrode is a semi-transparent electrode, the first electrode may be manufactured of a semi-transparent metal such as silver (Ag), gold (Au), magnesium (Mg), or an alloy thereof. When a semi-transparent metal is used as a first electrode, the organic-inorganic complex solar cell may have a micro cavity structure.

In an exemplary embodiment of the present specification, when the electrode is a transparent conductive oxide layer, as the electrode, it is possible to use an electrode in which a material having conductivity is doped on a flexible and transparent material such as plastic including polyethylene terephthalate (PET), polyethylene naphthalate (PEN), polypropylene (PP), polyimide (PI), polycarbonate (PC), polystyrene (PS), polyoxyethylene (POM), an AS resin (acrylonitrile styrene copolymer), an ABS resin (acrylonitrile butadiene styrene copolymer), triacetyl cellulose (TAC), polyarylate (PAR), and the like, in addition to glass and a quartz plate.

Specifically, the electrode may be indium tin oxide (ITO), fluorine doped tin oxide (FTO), aluminum doped zinc oxide (AZO), indium zinc oxide (IZO), ZnO—Ga₂O₃, ZnO—Al₂O₃ and antimony tin oxide (ATO), and the like, and more specifically, ITO.

According to an exemplary embodiment of the present specification, the second electrode may be a metal electrode. Specifically, the metal electrode may include one or two or more selected from the group consisting of silver (Ag), aluminum (Al), platinum (Pt), tungsten (W), copper (Cu), molybdenum (Mo), gold (Au), nickel (Ni), palladium (Pd), magnesium (Mg), chromium (Cr), calcium (Ca), and samarium (Sm).

In an exemplary embodiment of the present specification, the organic-inorganic complex solar cell may have an n-i-p structure. When the organic-inorganic complex solar cell according to the present specification has an n-i-p structure, the second electrode may be a metal electrode, an oxide/metal composite electrode, or a carbon electrode. Specifically, the second electrode may include gold (Au), silver (Ag), aluminum (Al), MoO₃/Au, MoO₃/Ag, MoO₃/Al, V₂O₅/Au, V₂O₅/Ag, V₂O₅/Al, WO₃/Au, WO₃/Ag, or WO₃/Al.

In an exemplary embodiment of the present specification, the n-i-p structure means a structure in which a first electrode, an electron transporting layer, a light absorbing layer, a first hole transporting layer, a second hole transporting layer, and a second electrode are sequentially stacked.

In an exemplary embodiment of the present specification, the organic-inorganic complex solar cell may have a p-i-n structure. When the organic-inorganic complex solar cell according to the present specification has a p-i-n structure, the second electrode may be a metal electrode.

In an exemplary embodiment of the present specification, the p-i-n structure means a structure in which a first electrode, a hole transporting layer, a light absorbing layer, a first electron transporting layer, a second electron transporting layer, and a second electrode are sequentially stacked.

In an exemplary embodiment of the present specification, the electron transporting layer may be formed by being applied onto one surface of a first electrode or coated in the form of a film by using a method such as sputtering, E-Beam, thermal deposition, spin coating, screen printing, inkjet printing, doctor blade, or gravure printing.

In the present specification, the hole transporting layer may be introduced by a method such as spin coating, dip coating, inkjet printing, gravure printing, spray coating, doctor blade, bar coating, gravure coating, brush painting, and thermal deposition.

### MODE FOR INVENTION

Hereinafter, the present specification will be described in detail with reference to Examples for specifically describing the present specification. However, the Examples according to the present specification may be modified in various forms, and it is not interpreted that the scope of the present specification is limited to the Examples described below in detail. The Examples of the present specification are provided to more completely explain the present specification to a person with ordinary skill in the art.

### Example

A first solution in which 4.5 wt % of nickel oxide (NiO) and 8 wt % of a dispersant based on nickel oxide nanoparticles were included in xylene was spin-coated onto an alkali-free glass substrate sputtered with indium tin oxide (ITO), and then heated at 150° C. Thereafter, a light absorbing layer including perovskite (FAₓMA₁₋ₓPBI_{y}Br_{3-y}, 0<x<1, 0<y<3) was formed, and then a second solution including 4.5 wt % of zinc oxide (ZnO) and 8 wt % of a dispersant based on zinc oxide nanoparticles was spin-coated thereon, and heated at 100° C. Additionally, a solution including (6,6)-phenyl-C-butyric acid-methyl ester (PCBM) was spin-coated thereon, and then Ag was vacuum deposited thereon.

### Comparative Example 1

A solution in which 2 wt % of titanium dioxide (TiO₂) was included in an isopropyl alcohol (IPA) solvent was spin-coated onto an alkali-free glass substrate sputtered with indium tin oxide (ITO), and then heated at 150° C. Thereafter, a light absorbing layer including perovskite (FAₓMA₁₋ₓPBI_{y}Br_{3-y}, 0<x<1, 0<y<3) was formed, and then a solution including 7 wt % of 2,2′,7,7′-tetrakis(N,N-di-p-methoxyphenylamine)-9,9′-spirobifluorene (Spiro-OMeTAD) was spin-coated thereon, and Ag was vacuum-deposited thereon.

### Comparative Example 2

A first solution in which 4.5 wt % of nickel oxide (NiO) and 8 wt % of a dispersant based on nickel oxide nanoparticles were included in xylene was spin-coated onto an alkali-free glass substrate sputtered with indium tin oxide (ITO), and then heated at 150° C. Thereafter, a light absorbing layer including perovskite (FAₓMA₁₋ₓPBI_{y}Br_{3-y}, 0<x<1, 0<y<3) was formed, and then a solution including PCBM was spin-coated thereon. Additionally, a second solution including 4.5 wt % of zinc oxide (ZnO) and 8 wt % of a dispersant based on zinc oxide nanoparticles was spin-coated thereon and heated at 100° C., and then Ag was vacuum-deposited.

Table 1 shows the performance of each of the organic-inorganic complex solar cells according to exemplary embodiments of the present specification, and FIG. 2 illustrates a scanning electron microscope (SEM) image of cross-section of the organic-inorganic complex solar cell manufactured in the Example of the present specification.

TABLE 1

| | PCE | J_{sc} | V_{oc} | FF |
|---|---|---|---|---|
| | (%) | (mA/cm²) | (V) | (%) |
| Example | 4.4 | 10.43 | 1.01 | 42.0 |
| Comparative Example 1 | 0.0 | 0.96 | 0.01 | 0.2 |
| Comparative Example 2 | 1.3 | 3.0 | 0.7 | 59.0 |

In Table 1, V_{oc}, J_{sc}, FF, and PCE mean an open-circuit voltage, a short-circuit current, a fill factor, and energy conversion efficiency, respectively. The open-circuit voltage and the short-circuit current are an X axis intercept and a Y axis intercept, respectively, in the fourth quadrant of the voltage-current density curve, and as the two values are increased, the efficiency of the solar cell is preferably increased. In addition, the fill factor is a value obtained by dividing the area of a rectangle, which may be drawn within the curve, by the product of the short-circuit current and the open-circuit voltage. The energy conversion efficiency may be obtained when these three values are divided by the intensity of the irradiated light, and the higher value is preferred.

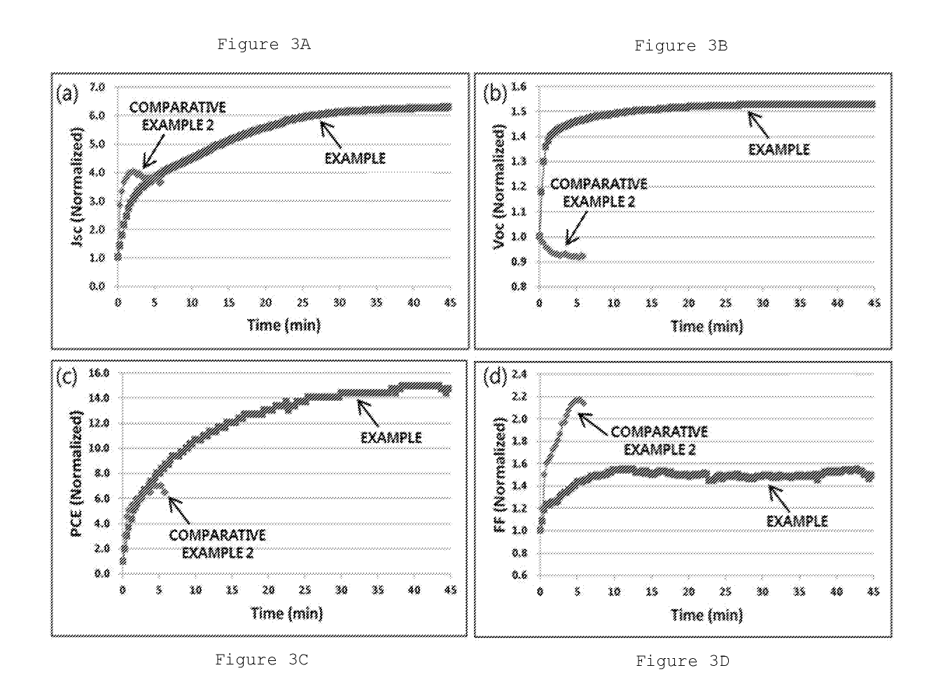

FIG. 3(A) illustrates a value of change in short-circuit current (J_{sc}) according to the time in each of the organic-inorganic complex solar cells manufactured in the Example and Comparative Example 2 of the present specification.

FIG. 3(B) illustrates a value of change in open-circuit voltage (V_{oc}) according to the time in each of the organic-inorganic complex solar cells manufactured in the Example and Comparative Example 2 of the present specification.

FIG. 3(C) illustrates a value of change in efficiency (PCE) according to the time in each of the organic-inorganic complex solar cells manufactured in the Example and Comparative Example 2 of the present specification.

FIG. 3(D) illustrates a value of change in fill factor (FF) according to the time in each of the organic-inorganic complex solar cells manufactured in the Example and Comparative Example 2 of the present specification.

The short-circuit current (J_{sc}), the open-circuit voltage (V_{oc}), the efficiency (PCE), and the fill factor (FF) in Table 1 and FIG. 3 were measured under 1SUN (100 mW/cm²), which is a standard light quantity of a solar simulator, by storing each of the organic-inorganic complex solar cells manufactured in the Example and Comparative Example 2 in a vacuum oven at 85° C. for 2 hours, and then taking out the organic-inorganic complex solar cells.

1. An organic-inorganic complex solar cell comprising:
a first electrode;
a first common layer provided on the first electrode;
a light absorbing layer provided on the first common layer, the light absorbing layer comprising a compound having a perovskite structure;
a second common layer provided on the light absorbing layer;
a third common layer provided on the second common layer; and
a second electrode provided on the third common layer,
wherein the first common layer comprises a first metal oxide nanoparticle,
the second common layer comprises a second metal oxide nanoparticle, and
the third common layer comprises a fullerene derivative.

2. The organic-inorganic complex solar cell of claim 1, wherein the compound having a perovskite structure is a compound of Chemical Formula 1 or 2:
AMX₃ [Chemical Formula 1]
A′_{y}A″_{(1-y)}M′X′_{Z}X″_{(3-z)} [Chemical Formula 2]
wherein in Chemical Formula 1 or 2,
A′ and A″ are different from each other, and A, A′, and A″ are each a monovalent cation selected from the group consisting of: CₙH₂ₙ₊₁NH₃, NH₄⁺, HC(NH₂)₂⁺, Cs⁺, NF₄⁺, NCl₄⁺, PF₄⁺, PCl₄⁺, CH₃PH₃⁺, CH₃AsH₃⁺, CH₃SbH₃⁺, PH₄⁺, AsH₄⁺, and SbH₄⁺;
M and M′ are each a divalent metal ion selected from the group consisting of: Cu²⁺, Ni²⁺, Co²⁺, Fe²⁺, Mn²⁺, Cr²⁺, Pd²⁺, Cd²⁺, Ge²⁺, Sn²⁺, Bi²⁺, Pb²⁺, and Yb²⁺;
X, X′, and X″ are each a halogen ion;
n is an integer from 1 to 9,
0<y<1; and
0<z<3.

3. The organic-inorganic complex solar cell of claim 1, wherein the first metal oxide nanoparticle and the second metal oxide nanoparticle each comprises Ni oxide, Cu oxide, Zn oxide, Ti oxide, or Sn oxide, and
the first metal oxide nanoparticle and the second metal oxide nanoparticle are different from each other.

4. The organic-inorganic complex solar cell of claim 1, wherein the first metal oxide nanoparticle comprises Ni oxide or Cu oxide.

5. The organic-inorganic complex solar cell of claim 1, wherein the second metal oxide nanoparticle comprises Zn oxide, Ti oxide, or Sn oxide.

6. A method for manufacturing an organic-inorganic complex solar cell, the method comprising:
forming a first electrode;
forming a first common layer on the first electrode;
forming a light absorbing layer comprising a compound having a perovskite structure on the first common layer;
forming a second common layer on the light absorbing layer;
forming a third common layer on the second common layer; and
forming a second electrode on the third common layer,
wherein the first common layer comprises a first metal oxide nanoparticle,
the second common layer comprises a second metal oxide nanoparticle, and
the third common layer comprises a fullerene derivative.

7. The method of claim 6, wherein forming of the first common layer comprises coating a first solution comprising a first metal oxide nanoparticle and a first dispersant onto the first electrode, and
forming of the second common layer comprises coating a second solution comprising a second metal oxide nanoparticle and a second dispersant onto the light absorbing layer.

8. The method of claim 7, wherein the first solution and the second solution each comprises a non-polar solvent.

9. The method of claim 7, wherein the first solution comprises the first dispersant in an amount of more than 0 wt % and 10 wt % or less based on the weight of the metal nanoparticle.

10. The method of claim 7, wherein the second solution comprises the second dispersant in an amount of more than 0 wt % and 10 wt % or less based on the weight of the metal nanoparticle.
